(19) United States
(12) Patent Application Publication
(10) Pub. No.: US 2026/0231444 A1
(43) Pub. Date: Aug. 6, 2026

(54) Trimmable Metal-Oxide-Semiconductor Capacitor

(71) Applicant: KYOCERA AVX Components Corporation, Fountain Inn, SC (US)

(72) Inventors: Jeff Borgman, Myrtle Beach, SC (US); Cory Nelson, Simpsonville, SC (US); Jessica Parry, Myrtle Beach, SC (US)

(21) Appl. No.: 19/455,915

(22) Filed: Jan. 22, 2026

Related U.S. Application Data
(60) Provisional application No. 63/751,870, filed on Jan. 31, 2025.

(51) Int. Cl. H10D 1/66; H10D 1/00; H10D 64/00

(52) U.S. Cl. CPC H10D 1/66; H10D 1/047; H10D 64/115

(57) ABSTRACT

Capacitors, capacitor assemblies, and methods of forming capacitors are provided. For example, a capacitor includes a substrate comprising a semiconductor material, the substrate having a first substrate surface; an oxide layer formed over the first substrate surface; a resistive layer formed over at least a portion of the oxide layer, the resistive layer having a resistive layer area; and a first conductive layer formed over at least a portion of the resistive layer, the first conductive layer having a first conductive layer area that is smaller than the resistive layer area. The capacitor has a capacitance value in a range from a minimum capacitance value to a maximum capacitance value, and the resistive layer area is configured to be trimmed to reduce the capacitance value of the capacitor to less than the maximum capacitance value.

### RELATED APPLICATIONS

The present application is a continuation based upon and claims priority to U.S. Provisional Patent Application Ser. No. 63/751,870, having a filing date of Jan. 31, 2025, which is incorporated herein by reference.

### FIELD

The subject matter of the present invention related generally to a semiconductor based capacitor assembly having selectively tunable capacitance values.

### BACKGROUND

Metal-oxide-semiconductor (MOS) capacitors provide a variety of benefits, such as temperature stability, generally high breakdown voltages, and low leakage currents. Thus, MOS capacitors may be desirable for use in a wide variety of applications, particularly those applications in which reliability when subjected to substantial mechanical and/or environmental stress is desired or necessary. However, some applications in which MOS capacitors may be desirable can require precision tunable capacitance of the capacitor. For instance, it may be desirable to finely tune the capacitance after the capacitor is installed in a circuit.

Consequently, there is a need for a MOS capacitor that can offer more variety to enable formation of dynamic capacitor arrays within a limited area. In particular, a MOS capacitor assembly that is finely tunable in a circuit may be useful, as well as a MOS capacitor assembly that is finely tunable prior to embedding in a substrate such as a circuit board substrate.

### SUMMARY

In accordance with one embodiment of the present invention, a capacitor comprises a substrate comprising a semiconductor material, the substrate having a first substrate surface; an oxide layer formed over the first substrate surface, the first substrate surface defined in an X-Y plane, the X-Y plane defined by an X-direction and a Y-direction perpendicular to the X-direction; a resistive layer formed over at least a portion of the oxide layer, the resistive layer having a resistive layer area in a first plane parallel to the X-Y plane; and a first conductive layer formed over at least a portion of the resistive layer, the first conductive layer having a first conductive layer area in a second plane parallel to the X-Y plane, the first conductive layer area smaller than the resistive layer area. The capacitor comprises a capacitance value in a range from a minimum capacitance value to a maximum capacitance value. The resistive layer area is configured to be trimmed to reduce the capacitance value of the capacitor to less than the maximum capacitance value.

In accordance with another embodiment of the present invention, a method of forming a capacitor comprises forming an oxide layer over a first substrate surface of a substrate, the substrate comprising a semiconductor material; forming a resistive layer over at least a portion of the oxide layer; forming a first conductive layer over at least a portion of the resistive layer; and trimming the resistive layer.

In accordance with another embodiment of the present invention, an embedded capacitor assembly comprises a circuit board substrate having a mounting surface; and a capacitor at least partially embedded within the circuit board substrate. The capacitor comprises a substrate comprising a semiconductor material, the substrate having a first substrate surface; an oxide layer formed over the first substrate surface, the first substrate surface defined in an X-Y plane, the X-Y plane defined by an X-direction and a Y-direction perpendicular to the X-direction; a resistive layer formed over at least a portion of the oxide layer, the resistive layer having a resistive layer area in a first plane parallel to the X-Y plane; and a first conductive layer formed over at least a portion of the resistive layer, the first conductive layer having a first conductive layer area in a second plane parallel to the X-Y plane, the first conductive layer area smaller than the resistive layer area. The capacitor comprises a capacitance value in a range from a minimum capacitance value to a maximum capacitance value, and the resistive layer area is configured to be trimmed to reduce the capacitance value of the capacitor to less than the maximum capacitance value.

### BRIEF DESCRIPTION OF THE DRAWINGS

A full and enabling disclosure of the present invention, including the best mode thereof, directed to one of ordinary skill in the art, is set forth more particularly in the remainder of the specification, which makes reference to the appended figures, in which:

FIG. 1A is a perspective view of a capacitor according to aspects of the present disclosure;

FIG. 1B is a top view of the capacitor of FIG. 1A;

FIG. 1C is a top view of the capacitor of FIG. 1A after trimming away a portion of the resistive layer according to an embodiment of the present disclosure;

FIG. 1D is a top view of the capacitor of FIG. 1A after trimming away a portion of the resistive layer according to another embodiment of the present disclosure;

FIG. 2A is a perspective view of a capacitor according to aspects of the present disclosure;

FIG. 2B is a top view of the capacitor of FIG. 2A;

FIG. 2C is a top view of the capacitor of FIG. 2A after trimming away a portion of the resistive layer;

FIG. 3A is a side view of another capacitor according to aspects of the present disclosure;

FIG. 3B is a side view of yet another capacitor according to aspects of the present disclosure;

FIG. 3C is a side view of still another capacitor according to aspects of the present disclosure;

FIG. 4A is a perspective view of another capacitor according to aspects of the present disclosure;

FIG. 4B illustrates the capacitor of FIG. 4A having an oxide layer within a first portion of a surface of a substrate of the capacitor and a second terminal within a second portion of the surface of the substrate;

FIG. 5 is a perspective view of a capacitor assembly including a capacitor and a mounting surface, such as a printed circuit board, according to aspects of the present disclosure;

FIG. 6A illustrates an embedded capacitor assembly including a capacitor embedded in a circuit board substrate according to aspects of the present disclosure;

FIG. 6B illustrates another embedded capacitor assembly including a capacitor embedded in a circuit board substrate according to aspects of the present disclosure; and

FIG. 7 is a flowchart of a method for forming a capacitor according to aspects of the present disclosure.

Repeat use of reference characters in the present specification and drawings is intended to represent same or analogous features or elements of the invention.

### DETAILED DESCRIPTION

It is to be understood by one of ordinary skill in the art that the present discussion is a description of exemplary embodiments only and is not intended as limiting the broader aspects of the present invention, which broader aspects are embodied in the exemplary construction.

Further, when a plurality of ranges are provided herein, any combination of a minimum value and a maximum value described in the plurality of ranges are contemplated by the present invention. For example, if ranges of “from about 20% to about 80%” and “from about 30% to about 70%” are described, a range of “from about 20% to about 70%” or a range of “from about 30% to about 80%” are also contemplated by the present invention.

Generally speaking, the present invention is directed to a precision tunable metal-oxide-semiconductor (MOS) capacitor. For example, the MOS capacitor (or simply, “capacitor”) can include a substrate, an oxide layer formed over a surface of the substrate, a resistive layer is formed over at least a portion of the oxide layer, and a conductive layer formed over at least a portion of the resistive layer. As described herein, an additional conductive layer is formed or disposed opposite the oxide layer such that the substrate disposed therebetween completes the capacitor. The resistive layer is trimmable, e.g., in situ, to achieve a desired capacitance. That is, the resistive layer can be trimmed to finely tune a capacitance value of the MOS capacitor.

An effective circuit formed by the MOS capacitor with the resistive layer is a resistor in line with a capacitor, which can render the MOS capacitor a higher equivalent series resistance (ESR) capacitor. Increased ESR can reduce the Q factor, or quality factor, of the capacitor and broaden the frequency response of the capacitor. A broadened frequency response of a MOS capacitor can improve the performance of bias lines in active radiofrequency (RF) devices, e.g., by providing filtered voltage to the active RF device. It will be appreciated that the quality factor or Q factor is the reactance of the capacitor divided by the ESR of the capacitor.

Additionally, or alternatively, a broadened frequency response due to increased ESR can enhance the performance of MOS capacitors in RF shunt applications and noise filtering applications. For example, a bias bank of RF active devices utilizing one or more MOS capacitors as described herein can have a reduced number of components, e.g., compared to a bias bank that does not utilize MOS capacitors having a resistive layer as described herein. A reduced number of components in the bias bank can increase reliability, decrease size, and improve active device performance of the bias bank. Other applications may include VCO, mixers, and cascade amplifiers voltage supply.

Further, the present inventors have found that the MOS capacitor of the present invention can allow for tighter tolerance and wider variance of the capacitance value of the capacitor. More particularly, the present inventors have found that the capacitor can be trimmed before or after installing the capacitor in a circuit, thereby enabling fine tuning of the capacitance value of the capacitor for applications requiring precision tunable capacitance. As examples, the capacitance value of the capacitor of the present invention can be tunable within the range of a ratio of the resistive layer to the conductive layer. More particularly, the area of the resistive layer can define a maximum capacitance value of the capacitor, and the area of the conductive layer can define a minimum capacitance value of the capacitor; trimming the resistive layer reduces its area to lower the capacitance of the capacitor within the range of the minimum capacitance value to the maximum capacitance value.

As stated, the MOS capacitor can include a substrate and an oxide layer formed over the substrate. The substrate of the MOS capacitor can include a semiconductor material, such as silicon, gallium arsenide, germanium, silicon carbide, strontium titanate, and/or mixtures thereof. The substrate can be doped with one or more suitable dopants, such as boron, arsenic, phosphorus, gallium, aluminum, indium, and antimony.

The oxide layer of the MOS capacitor can be formed over a surface of the substrate. The substrate surface can extend in an X-Y plane, e.g., in a longitudinal or X-direction and in a lateral or Y-direction that is perpendicular to the X-direction, with the X-direction and the Y-direction defining the X-Y plane. The oxide layer can extend in a plane parallel to the X-Y plane. The oxide layer can be or include silicon oxide, silicon oxynitride, and/or oxides of other example semiconductor materials described herein.

The oxide layer can be grown in situ on the substrate. Lithography (e.g., photolithography) techniques can be used to define the shape of the oxide layer. For instance, portions of the oxide layer can be removed through etching such that the oxide layer is shaped as desired.

The oxide layer can be formed over a portion of the substrate surface or over the entire substrate surface. For example, the oxide layer can extend to each edge of the substrate surface such that the oxide layer is formed over the entire substrate surface. In another embodiment, the oxide layer is contained within the perimeter of the substrate surface such that the oxide layer does not extend to any edge of the substrate surface. In yet another embodiment, the oxide layer extends to one or more edges, but not all of the edges, of the substrate surface.

As used herein, a layer that is “formed over” an object can include the layer being directly formed on the object and the layer being formed over one or more intermediate layers that are between the layer and the object. Further, formed “over” a bottom surface refers to outward from a center of the component.

The substrate surface can generally be smooth. For example, the substrate surface can be free of pores, trenches, or the like. The oxide layer can have a generally uniform thickness over the substrate surface. For example, the thickness of the oxide layer can vary less than 20% across the oxide layer, in some embodiments less than 10%, and in some embodiments less than 5%.

The resistive layer of the MOS capacitor can be formed over at least a portion of the oxide layer. The resistive layer has a resistive layer area in a first plane parallel to the X-Y plane. More particularly, the resistive layer can have a length in the X-direction and a width in the Y-direction, with the length and width defining an area in a plane that is parallel to the X-Y plane in which is defined the substrate surface. The resistive layer has a plurality of edges, e.g., four edges for a rectangular shaped resistive layer, that define a perimeter of the resistive layer, as well as the resistive layer area. The perimeter of the resistive layer may be contained within the perimeter of the substrate surface, e.g., in some embodiments, the edges of the resistive layer do not extend to the edges of the substrate surface, but in other embodiments, one or more edges of the resistive layer may extend to one or more edges of the substrate surface.

In some embodiments, the resistive layer may be a thin-film resistor. The thin-film resistor may be configured to exhibit a variety of resistance values, as desired. For example, in some embodiments the thin-film resistor may have a resistance that ranges from about 1 Ω to about 2,000 Ω, in some embodiments from about 2 Ω to about 1,000 Ω, in some embodiments from about 5 Ω to about 750 Ω, in some embodiments from about 10 Ω to about 500 Ω, in some embodiments from about 25 Ω to about 400 Ω.

The resistive layer of the thin-film resistor may be formed using a variety of thin film techniques as further described herein. The resistive layer of the thin-film resistor may be formed from a variety of suitable resistive materials. For example, the resistive layer may include tantalum nitride (TaN), silicon chromium (SiCr), nickel chromium (NiCr), tantalum aluminide, chromium silicon, titanium nitride, titanium tungsten, tantalum tungsten, oxides and/or nitrides of such materials, and/or any other suitable thin film resistive materials.

The conductive layer of the MOS capacitor can be formed over at least a portion of the resistive layer and have a conductive layer area defined in a second plane parallel to the X-Y plane. The conductive layer can be contained within a perimeter of the resistive layer. As such, the conductive layer area can be smaller than the resistive layer area. The conductive layer can be free of direct contact and/or direct electrical connection with the substrate. The conductive layer can be or include metal, such as aluminum, copper, gold, silver, nickel, or mixtures thereof.

The resistive layer can be configured to be trimmed, i.e., the resistive layer can be reduced in size. For instance, the resistive layer can be trimmed by a laser or any other suitable means. The resistive layer is trimmed without hitting the breakdown voltage of the oxide layer underneath the resistive layer. For example, a laser used to trim the capacitor can be set to a level below the breakdown voltage of the oxide layer.

The resistive layer can be trimmed to change a capacitance value of the capacitor to a specific value, i.e., a portion of the resistive layer can be removed to tune the capacitance of the capacitor. The capacitor can have a capacitance value in a range from a minimum capacitance value to a maximum capacitance value. The minimum capacitance value is defined by the conductive layer area, and the maximum capacitance value is defined by the resistive layer area prior to trimming. The resistive layer can be configured to be trimmed to reduce the capacitance value of the capacitor to less than the maximum capacitance value. For example, a length, a width, or both of the resistive layer can be exposed, i.e., not covered by the conductive layer, such that the resistive layer can be trimmed with the laser or other suitable device or means to reduce the resistive layer area to a reduced resistive layer area. Reducing the resistive layer area decreases a ratio of the resistive layer area to the conductive layer area, thereby reducing the capacitance value of the capacitor. The resistive layer area that is removed or trimmed away can be selected to reduce the capacitance value of the capacitor to a desired value, thereby tuning the capacitor.

In at least some embodiments, the resistive layer defines a trimmable area. For example, the trimmable area can be exposed, i.e., not covered by the conductive layer, such that the trimmable area is available for trimming or for removal. That is, the trimmable area of the resistive layer is free of the conductive layer that is formed over the resistive layer such that the trimmable area is exposed for trimming or removal.

The trimmable area can be defined adjacent one or more edges of the conductive layer. In some embodiments, the conductive layer is contained within the perimeter of the resistive layer such that the trimmable area is adjacent each edge of the conductive layer. In other embodiments, at least one edge of the conductive layer is aligned with at least one edge of the resistive layer such that the aligned edge(s) of the conductive layer and the resistive layer have the same position in the X-direction and the Y-direction and are aligned in a vertical or Z-direction that is perpendicular to both the X-direction and the Y-direction. The trimmable area is not defined adjacent such aligned edge(s), i.e., no trimmable area exists at such aligned edges but is defined where an edge of the resistive layer is spaced apart from an adjacent edge of the conductive layer in the X-direction, the Y-direction, or both.

In some embodiments, the capacitor includes only one conductive layer. In other embodiments, in addition to the conductive layer formed over the resistive layer, the MOS capacitor can also include an additional or a second conductive layer. For example, the conductive layer described above can be a first conductive layer and the additional conductive layer can be a second conductive layer, separate from the first conductive layer, that is formed over the substrate.

In some embodiments, the second conductive layer is formed over a surface of the substrate opposite the oxide layer. For example, the substrate may have a first substrate surface and a second substrate surface opposite the first substrate surface, and the oxide layer may be formed over the first substrate surface and the second conductive layer may be formed over the second substrate surface. It will be appreciated that, where the first substrate surface is defined in an X-Y plane, the second substrate surface extends in a plane parallel to the X-Y plane.

In other embodiments, the second conductive layer can be formed over the same surface of the substrate as the oxide layer. For example, the oxide layer can be formed over the first substrate surface, and the second conductive layer can also be formed over the first substrate surface. In such embodiments, the second conductive layer can be free of electrical connection to the oxide layer.

In some embodiments, the second conductive layer can be one terminal of a pair of terminals. For instance, the MOS capacitor can include a pair of terminals referred to individually as a first terminal and a second terminal. The first terminal can be connected with the first conductive layer. The second terminal can be connected with a surface of the substrate, such as the first substrate surface (on which the oxide layer is formed) or the second substrate surface (opposite the surface on which the oxide layer is formed). As used herein, “connected with” can refer to components that are in direct physical contact. “Connected with” can also refer to items that are physically connected by one or more intermediate conductive layers such that the items are in direct electrical connection (e.g., without a resistive layer or dielectric layer therebetween). For instance, the first terminal can be formed over the first conductive layer, and the second terminal can be formed over the first substrate surface or the second substrate surface as described herein.

In other embodiments, rather than the second conductive layer being one terminal of a pair of terminals, the one terminal of the pair of terminals can be connected with the second conductive layer. For example, as described above, the MOS capacitor can include a pair of terminals referred to individually as a first terminal and a second terminal. The first terminal can be connected with the first conductive layer, and the second terminal can be connected with the second conductive layer. For instance, the first terminal can be formed over the first conductive layer, and the second terminal can be formed over the second conductive layer.

One or more protective layers can be formed over the substrate. For example, where the oxide layer, resistive layer, and conductive layer are formed over a first substrate surface, one or more protective layers can be formed over a second substrate surface that is opposite the first substrate surface. In some embodiments, the first and second terminals can be exposed through the one or more protective layers for electrical connection when surface mounting the capacitor. Example materials for the protective layer(s) include benzocyclobutene (BCB), polyimide, silicon oxynitride, alumina (Al₂O₃), silica (SiO₂), silicon nitride (Si₃N₄), epoxy, glass, or another suitable material.

In some embodiments, the first and second terminals can be connected and arranged such that the oxide layer covers less than all of the first substrate surface. For example, the first terminal can be spaced apart from the second terminal in a Y-direction. An edge of the oxide layer can be aligned with an X-direction that is perpendicular to the Y-direction. An edge of the oxide layer can be spaced apart from an end of the substrate in the Y-direction. The second terminal can be connected with the first substrate surface at a location that is spaced apart from the oxide layer along the first substrate surface. For example, the second terminal can be located between the edge of the oxide layer and the end of the substrate. The edge of the oxide layer can be spaced apart from the second terminal by a distance that is greater than about 2 microns, in some embodiments greater than about 5 microns, in some embodiments greater than about 10 microns, and in some embodiments greater than about 15 microns.

The oxide layer can cover a first portion of the first substrate surface that is distinct from a second portion of the first substrate surface that is free of the oxide layer. The second terminal can be connected with the first substrate surface within the second portion of the first substrate surface. The second terminal can include an electrically conductive material that directly contacts the first substrate surface.

As described herein, in other embodiments, the second terminal can be formed over the second substrate surface such that the substrate is disposed between the oxide layer and the second terminal. In some embodiments, the second terminal can include an electrically conductive material that directly contacts the second substrate surface, and in other embodiments, the second terminal can include an electrically conductive material that directly contacts a second conductive layer that is formed over the second substrate surface.

Various thin-film techniques can be used to form thin-film layers of the capacitor, such as the first conductive layer, the second conductive layer, the resistive layer, the terminals, or the like. Examples of such techniques that may be employed include chemical deposition (e.g., chemical vapor deposition), PECVD (Plasma Enhanced Chemical Vapor Deposition) processing, physical deposition (e.g., sputtering), or any other suitable deposition technique for forming thin-film elements. Additional examples include any suitable patterning technique (e.g., photolithography), etching, and any other suitable subtractive technique for forming thin-film elements.

The thin-film layers can have a range of thicknesses. For example, the thin-film layers can have thicknesses that can range in some embodiments from about 0.001 micrometers (microns) to about 100 microns, in some embodiments from about 0.0375 microns to about 40 microns, in some embodiments from about 0.1 microns to about 30 microns, in some embodiments from about 0.2 microns to about 20 microns in some embodiments from about 0.4 microns to about 10 microns. For instance, in some embodiments, the resistive layer may have a thickness less than about 10 microns, in some embodiments less than about 8 microns, in some embodiments less than about 6 microns, and in some embodiments less than about 4 microns.

In some embodiments, the conductive layer formed over the resistive layer may be relatively small compared to the resistive layer, which defines the lower end of the capacitive value of the capacitor. By providing a relatively small conductive layer, only a relatively small area is available for current to flow through, which forces the current through the resistive layer and can increase resistance from the edges of the resistive layer to the relatively small conductive layer. However, as described herein, the resistive layer can be trimmed, which brings the resistive layer area closer to the conductive layer area and tunes the capacitance of the capacitor to a desired value.

The capacitor can be configured for surface mounting. For example, as described herein, in some embodiments each of the first terminal and the second terminal are exposed along the same surface of the substrate for surface mounting the capacitor. Using surface mounting techniques, the MOS capacitor can be free of electrical connections, such as wirebond connections, that cause high frequency perturbations and adversely affect high frequency performance. As such, a surface mounted MOS capacitor can generally have excellent high frequency performance.

In some embodiments, the capacitor can be configured for grid array type mounting, such as land grid array, ball grid array, or the like. The terminals can be exposed along the first substrate surface and contained within a perimeter of the first substrate surface. For example, the substrate can have a pair of end surfaces that are perpendicular to the first substrate surface, and the pair of end surfaces can be free of terminations, including the terminals. Further, the first terminal, the second terminal, or both can be spaced apart from a pair of opposite end edges of the first substrate surface by respective distances. The distances can be 10 microns or greater, in some embodiments 15 microns or greater, in some embodiments 20 microns or greater, in some embodiments 40 microns or greater, and in some embodiments 50 microns or greater.

In some aspects of the present subject matter, the MOS capacitor can be configured for embedding within a circuit board substrate, such as a printed circuit board; an embedded capacitor assembly can include a circuit board substrate having a MOS capacitor at least partially embedded therein. For instance, the first terminal and the second terminal can be exposed along opposite surfaces of the substrate, such as a top surface and a bottom surface of the substrate, and can be contained within a perimeter of the respective surface of the substrate and connected with one or more conductive traces and/or electronic components of the circuit board substrate. In other embodiments, the first terminal and the second terminal of the embedded capacitor can be exposed along the same surface of the substrate and connected with one or more conductive traces and/or electronic components of the circuit board substrate.

The circuit board substrate can be formed from any suitable material, such as FR4, polytetrafluoroethylene, or the like. One or more electronic components, such as capacitors, resistors, transistors, switches, and/or other electronic components can be mounted to the circuit board substrate. As used herein, “mounted to” the circuit board can include any type of connection to the circuit board substrate that provides electrical connectivity, such as surface mounting to a surface of the circuit board substrate, embedding within the circuit board substrate, or the like.

In some embodiments, the circuit board substrate can have a recessed opening in a mounting surface of the circuit board substrate, such as an upper surface or a lower surface. The recessed opening can be configured to receive an electronic component such that the electronic component is embedded within the circuit board substrate. For instance, a capacitor, such as the capacitors described herein, can be inserted within the recessed opening for embedding within the circuit board substrate. One or more electrically conductive terminations of the capacitor, such as the first and second terminals, can be coupled to the circuit board substrate. For instance, one or more vias can be formed in, on, or through the terminations to electrically connect the capacitor with one or more conductive traces of the circuit board substrate and/or one or more electronic components that are mounted to the circuit board substrate.

The first and second terminals of the capacitor can be formed from copper, such as by copper plating. Typically, solid copper may not be a suitable material for forming exposed terminations of an electronic component because copper is susceptible to oxidizing when exposed. As such, solder material such as an alloy of copper, tin, and gold, is often used to form electrical terminations for electronic components such as capacitors. However, the present inventors have found that forming the first and second terminals of the embeddable capacitor from copper, e.g., by plating solid copper over a conductive layer and/or over one or more surfaces of the capacitor substrate, can provide superior electrical connections without the risk of oxidizing when the capacitor is embedded within a circuit board substrate. For instance, the first and second terminals can be laser drilled to form direct electrical connections with the circuit board substrate and/or additional electronic components mounted to the circuit board substrate.

As described herein, the resistive layer of the capacitor can be trimmed to tune the capacitance of the capacitor. It will be appreciated that, in appropriate embodiments, such trimming of the resistive layer can be performed in situ. In other embodiments, the resistive layer is trimmed before surface mounting, embedding, or otherwise connecting the capacitor with a circuit board or other electronic component.

The specific features of the trimmable MOS capacitor, methods of forming a capacitor, and the capacitor assembly of the present invention may be better understood with reference to the accompanying figures.

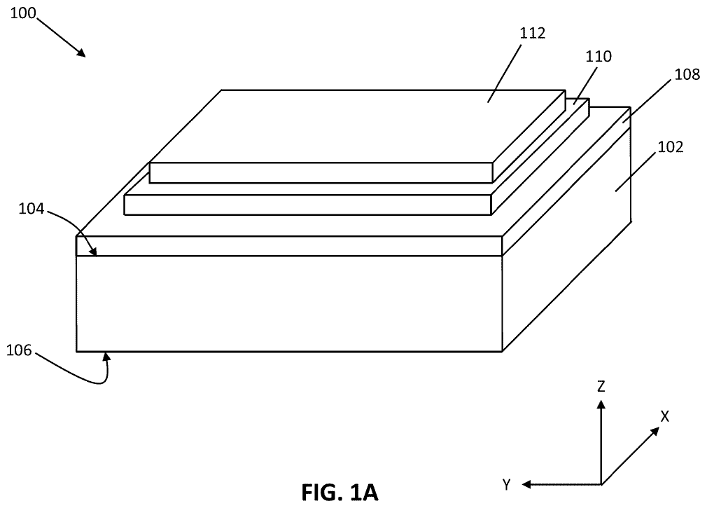

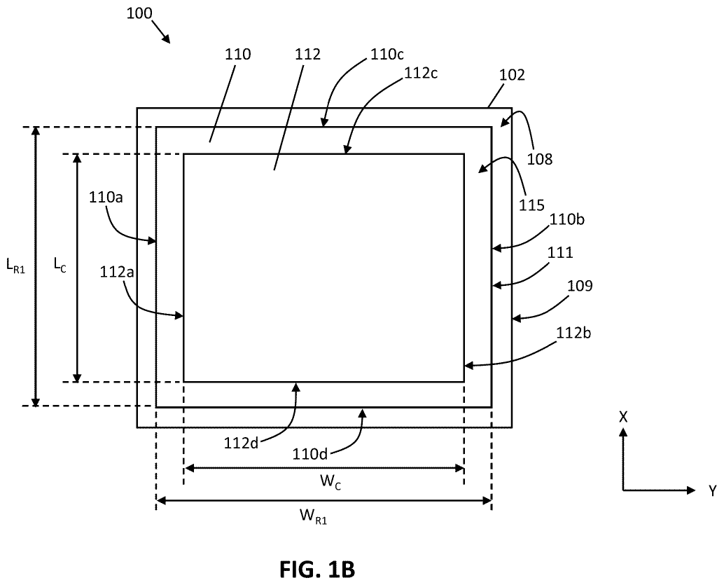

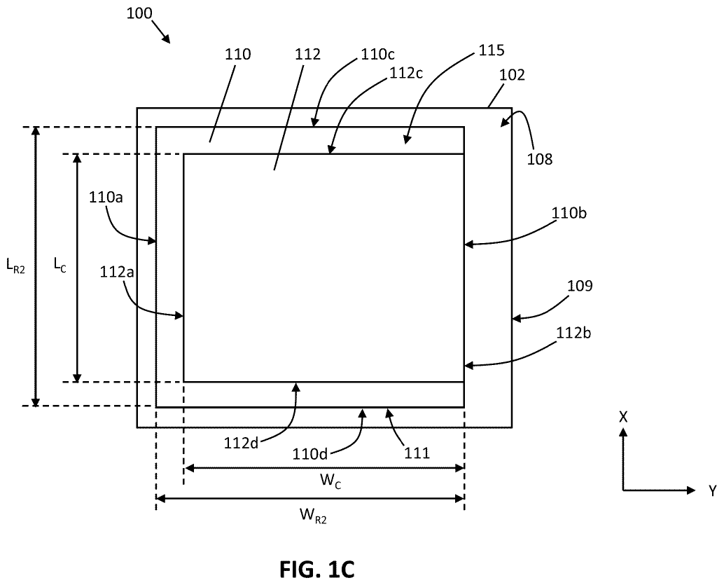

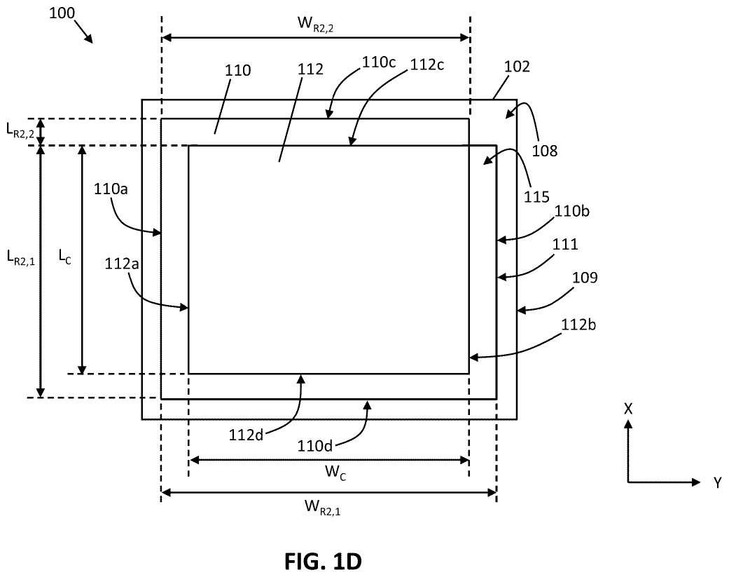

FIG. 1A is a perspective view of a capacitor 100 according to aspects of the present disclosure, and FIGS. 1B, 1C, and 1D are top views of the capacitor 100 with various resistive layer areas. Referring to FIG. 1A, the capacitor 100 has a substrate 102 including a semiconductor material, such as silicon. The substrate 102 has a first substrate surface 104 and a second substrate surface 106 opposite the first substrate surface 104. The first substrate surface 104 is defined in an X-Y plane that is defined by an X-direction and a Y-direction perpendicular to the X-direction.

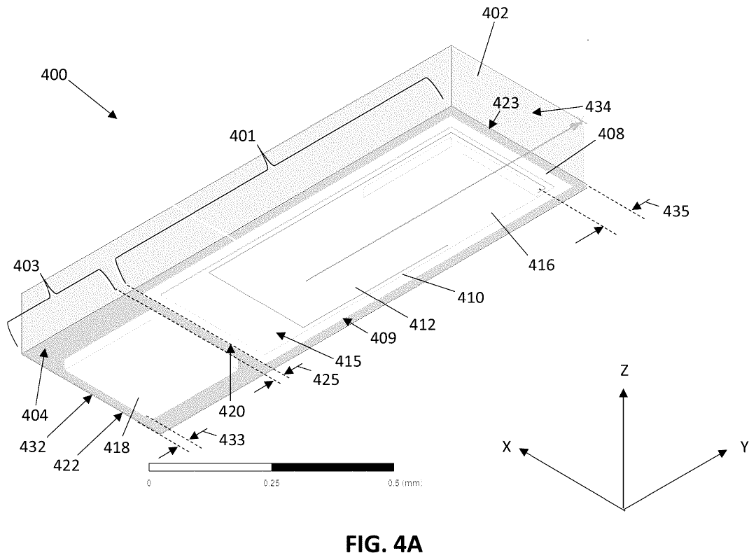

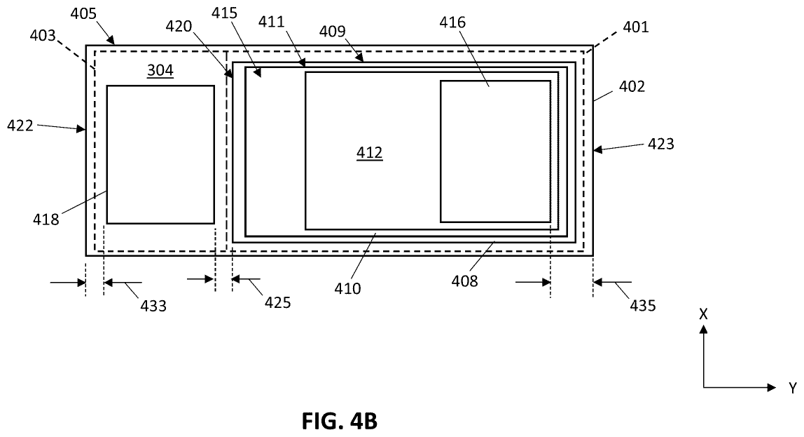

The capacitor 100 includes an oxide layer 108 formed over the first substrate surface 104 of the substrate 102. As examples, the oxide layer 108 can include silicon oxide or silicon oxynitride. In the depicted embodiments, the oxide layer 108 extends to the edges of the first substrate surface 104 and entirely covers the first substrate surface 104. However, in other embodiments, the oxide layer 108 may not extend to each edge of the first substrate surface 104, e.g., the oxide layer can be spaced apart from one or more edges of the first substrate surface 104, and in some embodiments, the oxide layer 108 can be contained within a perimeter of the first substrate surface 104, e.g., as illustrated in FIGS. 4A and 4B.

The capacitor 100 further includes a resistive layer 110 formed over at least a portion of the oxide layer 108. In FIGS. 1A-1D, the resistive layer 110 is contained within a perimeter 109 of the oxide layer 108 and does not extend to the edges of the oxide layer 108. In some embodiments, however, the resistive layer 110 can extend to one or more edges of the oxide layer 108. The resistive layer 110 is free of direct contact and/or direct electrical connection with the substrate 102.

In some embodiments, the resistive layer 110 can have a thickness less than about 10 microns. In some embodiments, the resistive layer 110 can be formed from tantalum nitride, and in other embodiments, the resistive layer 110 can be formed from chromium silicon. The resistive layer 110 can have other thicknesses and/or be formed from other materials as described elsewhere herein.

Referring still to FIGS. 1A-1D, the capacitor 100 further includes a conductive layer 112 formed over at least a portion of the resistive layer 110. Like the resistive layer 110, the conductive layer 112 is contained within the perimeter 109 of the oxide layer 108, as well as a perimeter 111 of the resistive layer 110. The conductive layer 112 is free of direct contact and/or direct electrical connection with the substrate 102. Further, the conductive layer 112 is free of direct contact and/or direct electrical connection with the oxide layer 108. The conductive layer 112 may be formed from a suitable conductive material, e.g., a metal, such that the capacitor 100 having a metal conductive layer 112, an oxide layer 108, and a semiconductor substrate 102 may be referred to as a metal-oxide-semiconductor capacitor or MOS capacitor.

Referring particularly to FIGS. 1A and 1B, the resistive layer 110 has a resistive area defined in a first plane parallel to the X-Y plane, and the conductive layer 112 has a conductive layer area in a second plane parallel to the X-Y plane. More particularly, as shown in FIG. 1B, the resistive layer 110 has a first length L_{R1} in the X-direction and a first width W_{R1} in the Y-direction, which define the resistive area (L_{R1} multiplied by W_{R1}). Similarly, the conductive layer 112 has a length L_{C} in the X-direction and a width W_{C} in the Y-direction, which define the resistive area (L_{C} multiplied by W_{C}).

In the depicted embodiment of FIG. 1B, each of the length L_{C} and the width W_{C} of the conductive layer 112 are smaller or shorter than the length L_{R1} and the width W_{R1}, respectively, of the resistive layer 110, such that the conductive layer area is smaller than the resistive layer area. Because the conductive layer 112 formed over the resistive layer 110 has a smaller area than the resistive layer area, a portion of the resistive layer area is exposed and not covered by the conductive layer area. The exposed resistive layer area is a trimmable area 115, i.e., the portion of the resistive layer 110 that may be trimmed to tune the capacitance value of the capacitor 100. More particularly, the resistive layer 110 defines a trimmable area 115, and the trimmable area 115 is free of the conductive layer 112.

Referring to FIGS. 1B-1D, the trimmable area 115 is defined adjacent at least one edge of the conductive layer 112. As shown in FIG. 1B, the trimmable area is defined adjacent each of a first edge 112a, a second edge 112b, a third edge 112c, and a fourth edge 112d of the conductive layer 112. The trimmable area may be reduced along one or more of the edges 112a, 112b, 112c, 112d of the conductive layer 112. For example, as shown in FIG. 1C, the width of the resistive layer 110 may be reduced from the first width W_{R1} shown in FIG. 1B to a second width W_{R2} shown in FIG. 1C. As depicted in FIG. 1C, the resistive layer 110 may be trimmed along the second edge 112b of the conductive layer 112 to remove the trimmable area 115 along the second edge 112b up to the second edge 112b. In the embodiment of FIG. 1C, after trimming, a second length L_{R2} of the resistive layer is unchanged with respect to the first length L_{R1} (FIG. 1B), i.e., the second length L_{R2} is the same as the first length L_{R1}. However, the second width W_{R2} is smaller than the first width W_{R1}, such that the resistive area after trimming, or a post-trimming resistive area, is smaller than the resistive area prior to trimming, which may be referred to as a pre-trimming resistive area. More particularly, the post-trimming resistive area may be calculated by multiplying the second length L_{R2} by the second width W_{R2}. Because the second width W_{R2} is smaller than the first width W_{R1} of the resistive layer 110, the post-trimming resistive area is smaller than the pre-trimming resistive area, which may be calculated by multiplying the first length L_{R1} by the second length L_{R2} as described above.

In other embodiments, such as depicted in FIG. 1D, only a portion of the trimmable area 115 adjacent the second edge 112b and the third edge 112c of the conductive layer 112 may be trimmed or removed. More specifically, in the illustrated embodiment of FIG. 1D, a corner of the resistive layer 110 is trimmed or removed. The post-trimming resistive area of the resistive layer 110 of FIG. 1D may be calculated by adding together the area of a first portion of the resistive layer 110 and the area of a second portion of the resistive layer 110. The area of the first portion has a length L_{R2,1} and a width W_{R2,1} such that the area of the first portion is the product of the length L_{R2,1} and the width W_{R2,1}. Similarly, the area of the second portion of the resistive layer 110 has a length L_{R2,2} and a width W_{R2,2} such that the area of the first portion is the product of the length L_{R2,2} and the width W_{R2,2}.

It will be appreciated that trimming or removing different amounts of the resistive layer 110 will produce a different capacitive value for the capacitor 100 shown in FIG. 1C from the capacitive value of the capacitor 100 shown in FIG. 1D (which are both different from the capacitive value of the capacitor 100 shown in FIG. 1B).

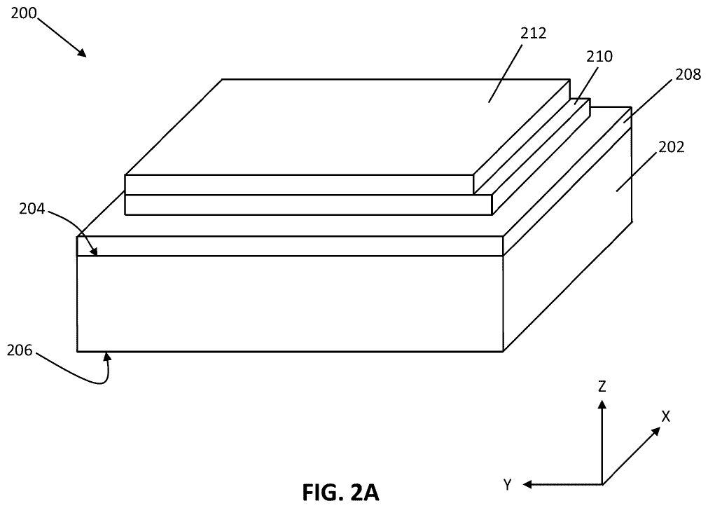

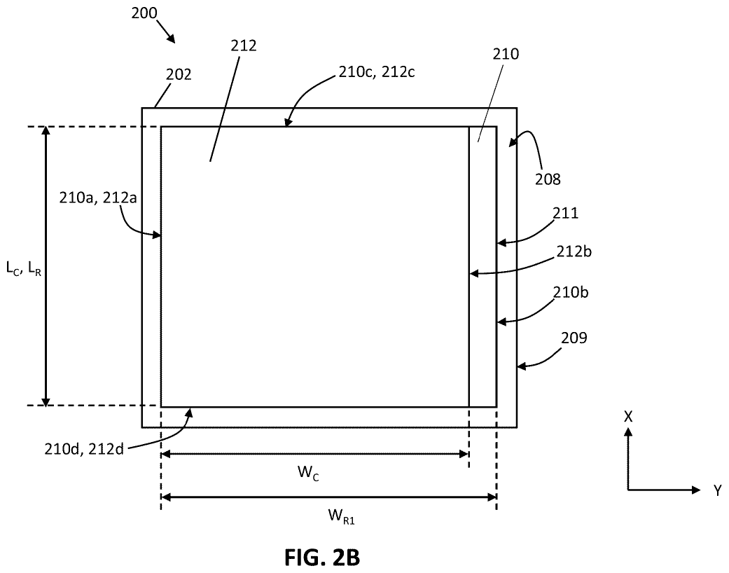

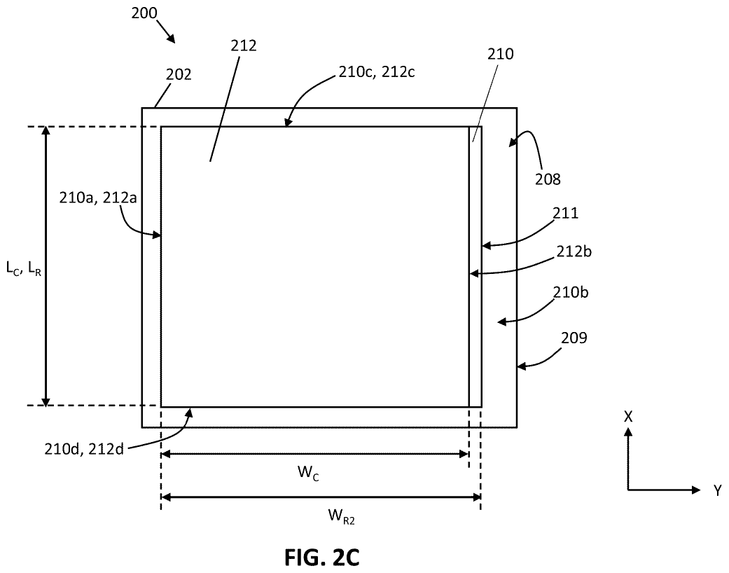

As shown in FIGS. 2A-2C, in other embodiments, at least one edge 112a, 112b, 112c, 112d of the conductive layer 112 is aligned with an edge 110a, 110b, 110c, 110d of the resistive layer 110 in the X-direction or the Y-direction. In such embodiments, the trimmable area 115 is defined adjacent only the edges of the resistive layer 110 that are spaced apart from an edge of the conductive layer 112.

The resistive layer area is configured to be trimmed by a laser. More particularly, a laser can be used to trim or remove at least a portion of the trimmable area 115. Because the resistive layer 110 is formed over the oxide layer 108, to avoid damaging the oxide layer 108, the laser is set to a power level less than a breakdown voltage of the oxide layer 108. In other embodiments, another suitable apparatus or technique may be used to remove the resistive layer 110 and thereby tune the capacitance of the capacitor 100.

As discussed above, the capacitor 100 has a capacitance value in a range from a minimum capacitance value to a maximum capacitance value. The resistive layer area is configured to be trimmed as described herein to reduce the capacitance value of the capacitor 100 to less than the maximum capacitance value, which is defined by the original, untrimmed area of the resistive layer 110. The conductive layer area defines the minimum capacitance value. Thus, by trimming the resistive layer area, with a laser or other suitable device or technique, the resistive layer area is reduced, which reduces the capacitance value of the capacitor 100 below the maximum capacitance value. If all of the trimmable area of the resistive layer 110 is removed such that the resistive layer area is the same as the conductive layer area, the capacitance value of the capacitor 100 is lowered to the minimum capacitance value.

FIGS. 2A through 2C illustrate other embodiments of a capacitor of the present subject matter. FIG. 2A is a perspective view of a capacitor 200 according to aspects of the present disclosure, and FIGS. 2B and 2C are top views of the capacitor 200 with various resistive layer areas. It will be appreciated that the capacitor 200 is similar to the capacitor 100 described above, with similar reference numbers denoting the same or similar features.

For example, referring to FIG. 2A, the capacitor 200 has a substrate 202 including a semiconductor material, such as silicon. The substrate 202 has a first substrate surface 204 and a second substrate surface 206 opposite the first substrate surface 204, with the first substrate surface 204 defined in an X-Y plane that is defined by an X-direction and a Y-direction perpendicular to the X-direction.

The capacitor 200 includes an oxide layer 208 formed over the first substrate surface 204 of the substrate 202. The oxide layer 208 can include, e.g., silicon oxide or silicon oxynitride. Although the oxide layer 208 depicted in FIGS. 2A-2C extends to the edges of the first substrate surface 204 and entirely covers the first substrate surface 204, in other embodiments, the oxide layer 208 may not extend to each edge of the first substrate surface 204.

The capacitor 200 further includes a resistive layer 210 formed over at least a portion of the oxide layer 208. For example, the resistive layer 210 can be contained within a perimeter 209 of the oxide layer 208 as shown in FIGS.-2C, but in some embodiments, the resistive layer 210 can extend to one or more edges of the oxide layer 208. The resistive layer 210 is free of direct contact and/or direct electrical connection with the substrate 202.

In some embodiments, the resistive layer 210 can have a thickness less than about 10 microns. In some embodiments, the resistive layer 210 can be formed from tantalum nitride, and in other embodiments, the resistive layer 210 can be formed from chromium silicon. The resistive layer 210 can have other thicknesses and/or be formed from other materials as described elsewhere herein.

As shown in FIGS. 2A-2C, the capacitor 200 further includes a conductive layer 212 formed over at least a portion of the resistive layer 210. Like the resistive layer 210, the conductive layer 212 is contained within the perimeter 209 of the oxide layer 208, and the conductive layer 212 is also contained within a perimeter 211 of the resistive layer 210. The conductive layer 212 is free of direct contact and/or direct electrical connection with the substrate 202. Further, the conductive layer 212 is free of direct contact and/or direct electrical connection with the oxide layer 208. The conductive layer 212 may be formed from a suitable conductive material, e.g., a metal, such that the capacitor 200 having a metal conductive layer 212, an oxide layer 208, and a semiconductor substrate 202 may be referred to as a metal-oxide-semiconductor capacitor or MOS capacitor.

As with the capacitor 100, the resistive layer 210 of the capacitor 200 has a resistive area defined in a first plane parallel to the X-Y plane, and the conductive layer 212 has a conductive layer area in a second plane parallel to the X-Y plane. Referring to FIG. 2B, the resistive layer 210 has a length L_{R} in the X-direction and a first width W_{R1} in the Y-direction, which define the resistive area (L_{R} multiplied by W_{R1}). Similarly, the conductive layer 212 has a length L_{C} in the X-direction and a width W_{C} in the Y-direction, which define the resistive area (L_{C} multiplied by W_{C}).

In the depicted embodiment of FIG. 2B, the width W_{C} of the conductive layer 212 is smaller or shorter than the first width W_{R1} of the resistive layer 210, such that the conductive layer area is smaller than the resistive layer area. Because the conductive layer 212 formed over the resistive layer 210 has a smaller area than the resistive layer area, a portion of the resistive layer area is exposed and not covered by the conductive layer area. The exposed resistive layer area is a trimmable area 215, i.e., the portion of the resistive layer 210 that may be trimmed to tune the capacitance value of the capacitor 200. More particularly, the resistive layer 210 defines a trimmable area 215, and the trimmable area 215 is free of the conductive layer 212.

In the embodiment of FIGS. 2A-2C, a first edge 212a, a third edge 212c, and a fourth edge 212d of the conductive layer 212 are aligned in the X-direction and the Y-direction with a first edge 210a, a third edge 210c, and a fourth edge 210d of the resistive layer 210. As such, referring to FIG. 2B, the trimmable area 215 of the resistive layer 210 is defined adjacent a second edge 212b of the conductive layer 212. The trimmable area 215 may be reduced along the second edge 212b of the conductive layer 212. For example, as shown in FIG. 2C, the width of the resistive layer 210 may be reduced from the first width W_{R1} shown in FIG. 2B to a second width W_{R2} shown in FIG. 2C. That is, the resistive layer 210 may be trimmed along the second edge 212b of the conductive layer 212 to remove at least a portion of the trimmable area 215 along the second edge 212b. In other embodiments, a different portion of the trimmable area 215 may be removed, e.g., similar to the embodiment of the capacitor 100 shown in FIG. 1D. In still other embodiments, all of the trimmable area 215 may be removed to reduce the resistive layer area to be equal to the conductive layer area and thereby reduce the capacitance value of the capacitor to the minimum capacitance value. More particularly, as described herein, the capacitor 200 has a capacitance value in a range from a minimum capacitance value, which is defined by the conductive layer area, to a maximum capacitance value, which is defined by the original, untrimmed area of the resistive layer 210. Accordingly, by trimming the resistive layer 210 to reduce its area, with a laser or other suitable device or technique as described herein, the capacitance value of the capacitor 200 is reduced below the maximum capacitance value. If all of the trimmable area of the resistive layer 210 is removed such that the resistive layer area is the same as the conductive layer area, the capacitance value of the capacitor 200 is lowered to the minimum capacitance value.

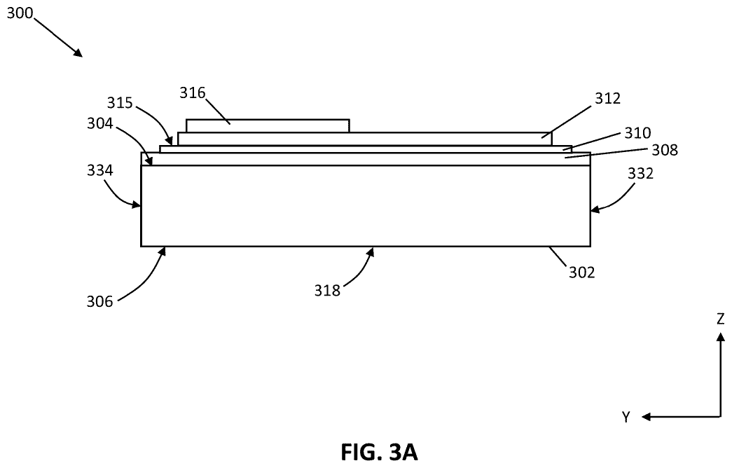

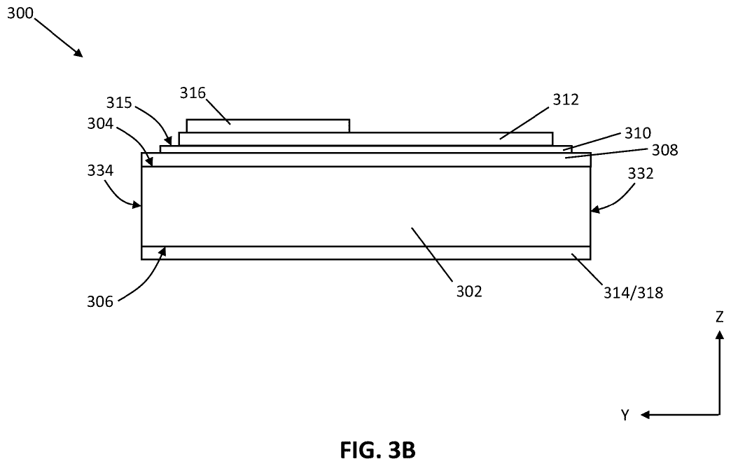

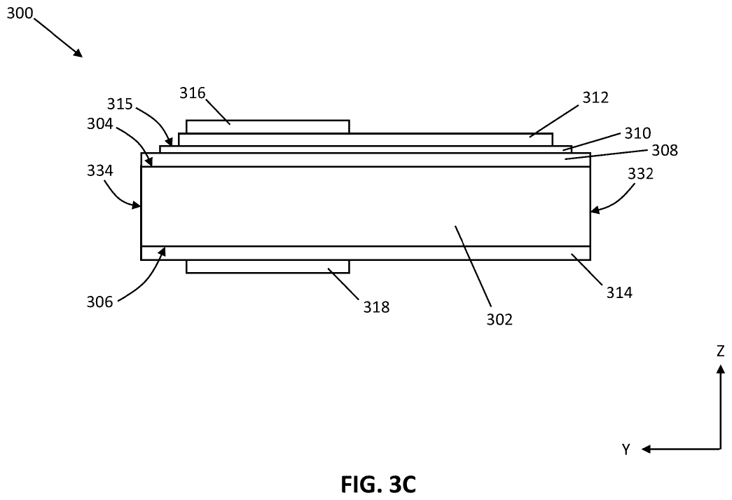

Referring to FIGS. 3A through 3C, side views are provided of various embodiments of a capacitor 300 according to aspects of the present disclosure. Similar reference numerals are used in FIGS. 3A through 3C as FIGS. 1A-1D and FIGS. 2A-2C. For example, the capacitor 300 includes a substrate 302 including a semiconductor material, with an oxide layer 308 formed over a first substrate surface 304 of the substrate 302. A resistive layer 310 is formed over at least a portion of the oxide layer 308, and a first conductive layer 312 is formed over at least a portion of the resistive layer 310. The resistive layer 310 defines a trimmable area 315, which can be trimmed or removed as discussed above to tune the capacitance value of the capacitor 300.

In the embodiments shown in FIGS. 3B and 3C, a second conductive layer 314 is formed over a second substrate surface 306 of the substrate 302, with the second substrate surface 306 opposite the first substrate surface 304. The second conductive layer 314 can extend over the entirety of the second substrate surface 306 as shown in FIGS. 3B and 3C. Alternatively, the second conductive layer 314 could be offset from one or more edges of the substrate 302, e.g., similar to the oxide layer 308, resistive layer 310, and first conductive layer 312 formed over the first substrate surface 304 of the substrate 302, such that the second conductive layer 314 extends over a portion of the second substrate surface 306.

A pair of terminals can be connected with the capacitor. Each terminal of the pair of terminals can include an electrically conductive material, such as gold, copper, another suitable metal, or other conductive material. In some embodiments, at least one of the first conductive layer 312 or the second conductive layer 314 is one terminal of a pair of terminals. For example, the first conductive layer 312 and the second conductive layer 314 each may form a respective one terminal of a pair of terminals.

In other embodiments, only one of the first conductive layer 312 or the second conductive layer 314 may form one terminal of a pair of terminals, and in still other embodiments, neither the first conductive layer 312 nor the second conductive layer 314 may form a terminal of a pair of terminals. For instance, as shown in FIGS. 3A through 3C, a first terminal 316 of the pair of terminals can be connected with the first conductive layer 312.

Further, the first terminal 316 can be located closer to one end surface 334 of a pair of end surfaces 332, 334 of the substrate 302 than the other end surface 332 of the pair of end surfaces 332, 334. For example, the substrate can include a first end surface 332 and a second end surface 334 that are opposite one another along the Y-direction and are perpendicular to the first substrate surface 304 and second substrate surface 306 of the substrate 302. As shown in FIGS. 3A through 3C, the first terminal 316 can be disposed closer to the second end surface 334 than the first end surface 332. In other embodiments, the first terminal 316 can be disposed closer to the first end surface 332 than the second end surface 334. In still other embodiments, the first terminal 316 may be disposed equidistant from the first end surface 332 and the second end surface 334 along the Y-direction.

A second terminal 318 of the pair of terminals can be connected with the substrate 302 or the second conductive layer 314. For example, the capacitor 300 can include the second terminal 318 on the second substrate surface 306 of the substrate 302. As shown in FIG. 3A, the second terminal 318 can be formed by the bare material of the second substrate surface 306 of the substrate 302. Alternatively, referring to FIG. 3B, the second terminal 318 can be formed from the second conductive layer 314 formed over the second substrate surface 306 of the substrate 302, which is opposite the first substrate surface 304 in the Z-direction. Referring to FIG. 3C, in other embodiments, the second terminal 318 can be formed over the second conductive layer 314, such that the second conductive layer 314 is disposed between the second terminal 318 and the substrate 302. The second terminal 318 may be aligned with the first terminal 316 in the Z-direction, as shown in FIG. 3C, or the second terminal 318 may be offset from the first terminal 316 in the Z-direction. For instance, the second terminal 318 may be formed closer to the first end surface 332 than the second end surface 334. In any of these configurations, the oxide layer 308 is connected in series between the first conductive layer 312 and the second conductive layer 314 to form a capacitor between the first terminal 316 and the second terminal 318.

In still other embodiments, each of the second conductive layer 314 and the second terminal 318 can be formed over the second substrate surface 306 of the substrate 302, without the second terminal 318 being formed over the second conductive layer 314, e.g., the second conductive layer 314 can be formed over one portion of the second substrate surface 306 and the second terminal 318 can be formed over another, separate portion of the second substrate surface 306.

In any event, the pair of terminals 316, 318, whether formed separately from the first conductive layer 312 and the second conductive layer 314 or formed by the first conductive layer 312 and/or the second conductive layer 314, are connected to various layers or the substrate 302 of the capacitor 300 such that the capacitor 300 includes a resistor and a capacitor formed in series with one another. The resistive layer 310 includes a trimmable area 315 that can be trimmed in situ or before mounting the capacitor 300 to adjust the capacitance value of the capacitor 300 to a desired capacitance value, as described above with respect to FIGS. 1A-2C.

Referring now to FIGS. 4A and 4B, a perspective bottom view and a bottom view are provided of a capacitor 400 according to aspects of the present disclosure. Similar reference numerals are used in FIGS. 4A and 4B as in FIGS. 1A-3C. For example, the capacitor 400 includes a substrate 402 including a semiconductor material, with an oxide layer 408 formed over a first substrate surface 404 of the substrate 402. A resistive layer 410 is formed over at least a portion of the oxide layer 408, and a conductive layer 412 is formed over at least a portion of the resistive layer 410. The resistive layer 410 can be contained within a perimeter 409 of the oxide layer 408, and the conductive layer 412 can be contained within a perimeter 411 of the resistive layer 410. The resistive layer 410 includes a trimmable area 415, which can be trimmed or removed to tune the capacitance value of the capacitor 400 as discussed above with respect to the capacitors 100 and 200.

In the embodiment shown in FIGS. 4A and 4B, each of a first terminal 416 and a second terminal 418 can be exposed along the first substrate surface 404 of the substrate 402 for surface mounting the capacitor 400. The first terminal 416 can be formed over the conductive layer 412. The first terminal 416 can be spaced apart from the second terminal 418 in a Y-direction. An edge 420 of the oxide layer 408 can be aligned with an X-direction that is perpendicular to the Y-direction. The edge 420 of the oxide layer 408 can be spaced apart from an end edge 422 of the substrate 402 in the Y-direction.

The second terminal 418 can be co-planar with the oxide layer 408. For example, each of the second terminal 418 and the oxide layer 408 can be formed exclusively on the first substrate surface 404 of the substrate 402. The second terminal 418 can be connected with the first substrate surface 404 of the substrate 402 at a location that is spaced apart from the oxide layer 408 along the first substrate surface 404 of the substrate 402. For instance, the second terminal 418 can be located between the edge 420 of the oxide layer 408 and the end 422 of the substrate 402. The edge 420 of the oxide layer 408 can be spaced apart from the second terminal 418 by a distance 425. In some embodiments, the distance 425 can be greater than about 2 microns.

Referring still to FIGS. 4A and 4B, the oxide layer 408 can be formed within a first portion 401 of the first substrate surface 404 of the substrate 402. The first portion 401 of the first substrate surface 404 of the substrate 402 can be distinct from a second portion 403 of the first substrate surface 404 of the substrate 402. The second portion 403 of the first substrate surface 404 can be free of the oxide layer 408.

The second terminal 418 can be connected with the first substrate surface 404 within the second portion 403 of the first substrate surface 404. In some embodiments, the second terminal 418 can directly contact the first substrate surface 404 of the substrate 402. However, in other embodiments, the second terminal 418 can be electrically connected with the first substrate surface 404 of the substrate 402 via one or more suitable conductive layers between the second terminal 418 and the first substrate surface 404. In any event, the pair of terminals 416, 418 are connected to various layers or the substrate 402 of the capacitor 400 such that the capacitor 400 includes a resistor and a capacitor formed in series with one another.

Each of the first terminal 416 and the second terminal 418 can include an electrically conductive material, such as gold, copper, another suitable metal, or other conductive material. The substrate 402 can include a semiconductor material, such as silicon. The oxide layer 408 can include, e.g., silicon oxide or silicon oxynitride.

The capacitor 400 can be configured for grid array type mounting, such as ball grid array type mounting or land grid array type mounting. The terminals 416, 418 can be exposed along the first substrate surface 404 and contained within a perimeter 405 of the first substrate surface 404 of the monolithic substrate 402 in an X-Y plane lying in each of the X-direction and the Y-direction.

As another example, the substrate 402 can have a pair of end surfaces 432, 434 that are perpendicular to the first substrate surface 404 of the monolithic substrate 402. The pair of end surfaces 432, 434 can be free of terminations, including the terminals 416, 418. As a further example, the first terminal 416, the second terminal 418, or both can be spaced apart from the pair of opposite end edges 422, 423 of the first substrate surface 404 of the monolithic substrate 402 by respective distances 433, 435. The distances 433, 435 can be 10 microns or greater. Further, the distances 433, 435 can be equal to one another or different from one another, e.g., one of the distances 433, 435 can be greater than the other of the distances 433, 435.

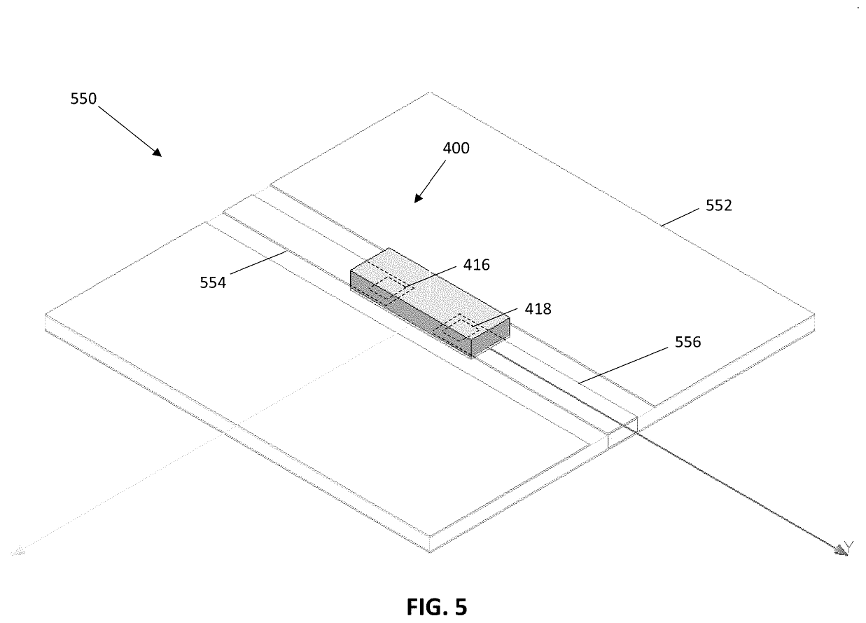

FIG. 5 is a perspective view of a capacitor assembly 550 including the capacitor 400 of FIGS. 4A and 4B and a mounting surface 552, such as a printed circuit board. The first terminal 416 of the capacitor 400 can be connected with a first conductive trace 554 of the mounting surface 552. The second terminal 418 of the capacitor 400 can be connected with a second conductive trace 556 of the mounting surface 552. As shown in FIG. 5, the capacitor 400 can be configured as a flip chip such that the first substrate surface 404 (FIGS. 4A, 4B) is opposite the mounting surface 552.

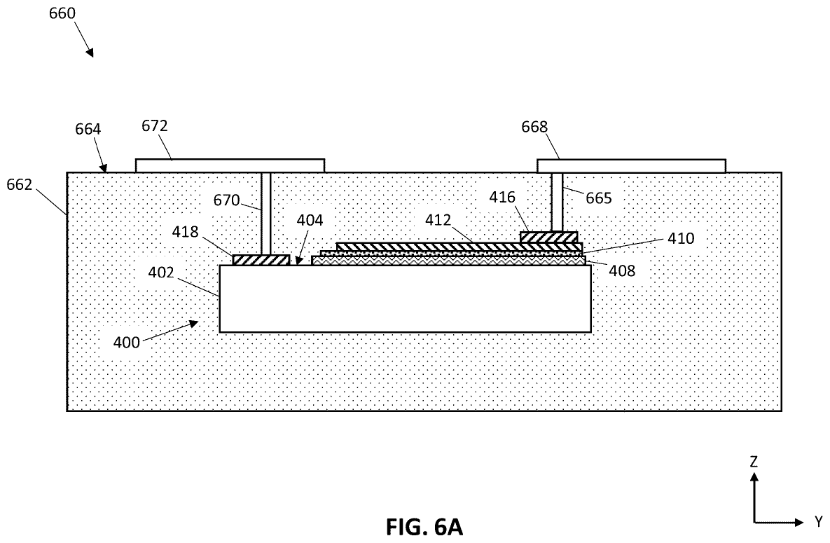

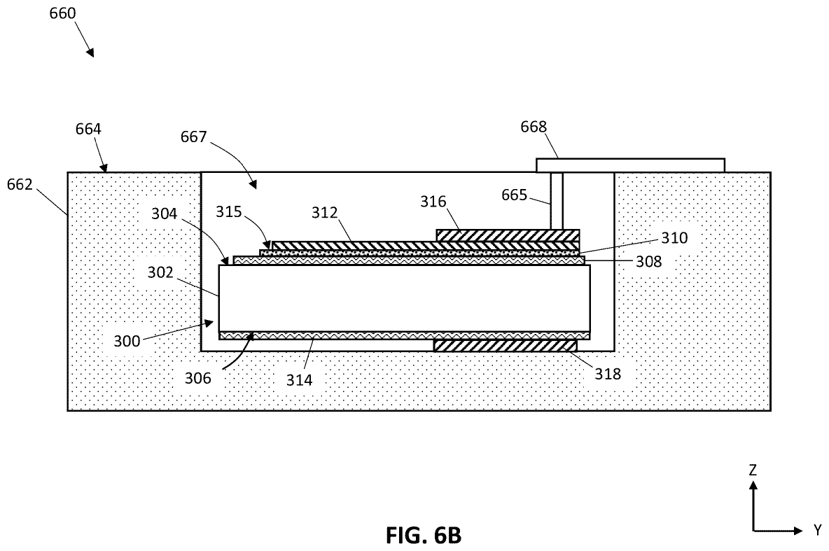

FIGS. 6A and 6B each illustrate an embedded capacitor assembly 660 including a capacitor embedded in a circuit board substrate 662 according to aspects of the present disclosure. In FIG. 6A, a capacitor 400 is embedded in the circuit board substrate 662, and in FIG. 6B, a capacitor 300 is embedded in the circuit board substrate 662. The capacitor 400 can generally be configured similar to the capacitor 400 of FIGS. 4A and 4B, and the capacitor 300 can generally be configured similar to the capacitor 300 of FIGS. 3A-3C. In other embodiments, other capacitors, such as the capacitor 100 or the capacitor 200 described above with respect to FIGS. 1A-1D and FIGS. 2A-2C, respectively, can be embedded in the circuit board substrate 662.

The circuit board substrate 662 can be, e.g., a printed circuit board and can be formed from any suitable material. For example, the printed circuit board can be formed from a material such as FR4, polytetrafluoroethylene, or the like. The circuit board substrate 662 includes a mounting surface 664.

The capacitor can be at least partially embedded within the circuit board substrate 662 of the embedded capacitor assembly 660. As shown in FIG. 6A, a first via 665 can extend from the first terminal 416 of the capacitor 400 toward the mounting surface 664 and connect to a first conductive layer 668 formed over the mounting surface 664. The first via 665 of the embedded capacitor assembly 660 can electrically connect the first terminal 416 with the first conductive layer 668.

Referring still to FIG. 6A, a second via 670 can extend from the second terminal 418 of the capacitor 400 toward the mounting surface 664 and connect to a second conductive layer 672 formed over the mounting surface 664. The second via 670 of the embedded capacitor assembly 660 can electrically connect the second terminal 418 with the second conductive layer 672.

Alternatively, the vias 665, 670 can extend toward the mounting surface 664 and connect with one or more intermediate layers (e.g., embedded within the circuit board substrate 662), which can in turn be electrically connected with the first conductive layer 668 and/or the second conductive layer 672. The first via 665 can form at least a portion of an electrical connection between the first terminal 416 of the capacitor 400 and the first conductive layer 668 formed over the mounting surface 664. Similarly, the second via 670 can form at least a portion of an electrical connection between the second terminal 418 of the capacitor 400 and the second conductive layer 672 formed over the mounting surface 664. As such, the conductive layers 668, 672 can be used to facilitate electrical connections with the capacitor 400. However, it should be understood that, in other embodiments, one or both of the terminals 416, 418 can be exposed along the mounting surface 664. In such an embodiment, the embedded capacitor assembly 660 can be free of one or both of the vias 665, 670.

Although in FIG. 6A the first and second terminals 416, 418 are shown at different locations along the Z-direction, it will be appreciated that the difference in height between the upper surfaces of the first and second terminals 416, 418 may be exaggerated in FIG. 6A for purposes of illustration only. For example, the relative thickness of the layers 408, 410, 412 may be exaggerated to better illustrate the layers in FIG. 6A. It will be understood that a surface of the first and second terminals 416, 418 can be defined in a common X-Y plane along the Z-direction to facilitate surface mounting of the capacitor 400 as described above with respect to FIG. 5.

As previously stated, the capacitor embedded in the circuit board substrate 662 could be configured similar to the capacitor 100 of FIGS. 1A-1D, the capacitor 200 of FIGS. 2A-2C, or the capacitor 300 of FIGS. 3A-3C. For example, referring to FIG. 6B, where the embedded capacitor is configured similarly to the capacitor 300 described herein, the embedded capacitor assembly 660 may include one via and one conductive layer on the mounting surface 664, such as via 665 that extends between the first terminal 316 and conductive layer 668 on the mounting surface 664. In such embodiments, via 670 may extend between the second terminal 318 and conductive layer 672 disposed at another location within or on the circuit board substrate 662 not shown in FIG. 6B. Alternatively, or additionally, the second terminal 318 may be electrically connected to the circuit board substrate 662 in other ways, such as through a ground plane defined within the circuit board substrate 662.

As depicted in FIG. 6B, the mounting surface 664 can have an opening 667 that is recessed into the circuit board substrate 662. To minimize its height profile on the board, the capacitor 300 can be embedded within the opening 667 and attached to the circuit board substrate 662 using known techniques. For example, using known techniques, one or more vias can connect one or more terminals of the capacitor 300 with one or more conductive traces of the circuit board substrate 662, as further described herein.

Embedding the capacitor 300 in the circuit board substrate 662 within the opening 667 can facilitate in situ trimming of the resistive layer 310 to fine tune the capacitance value of the capacitor 300 for the circuit. More particularly, the opening 667 allows access to the trimmable area 315 of the resistive layer 310 after the capacitor 300 is mounted with respect to the circuit board substrate 662. As such, the resistive layer 310 of the depicted capacitor 300 could be trimmed after mounting, although in other embodiments, the resistive layer 310 could be trimmed prior to mounting. In still other embodiments, the resistive layer 310 could be trimmed both prior to mounting and after mounting, e.g., to fine tune the capacitor 300 for the circuit.

Referring to still FIG. 6B, the first terminal 316 and the second terminal 318 are formed over opposite surfaces of the substrate 302 of the illustrated capacitor 300. For example, the first terminal 316 is formed over the first substrate surface 304, which may be an upper surface of the substrate 302, and the second terminal 318 is formed over the second substrate surface 306, which may be a lower surface of the substrate 302. As shown in FIG. 6B, a via 665 can extend from the first terminal 316 of the capacitor 300 toward the mounting surface 664 and connect to a conductive layer 668 formed over the mounting surface 664. The via 665 of the embedded capacitor assembly 660 can electrically connect the first terminal 316 with the first conductive layer 668, which may be, e.g., a conductive trace of the circuit board substrate 662. Alternatively, the via 665 can extend toward the mounting surface 664 and connect with one or more intermediate layers (e.g., embedded within the circuit board substrate 662), which can in turn be electrically connected with the conductive layer 668. The via 665 can form at least a portion of an electrical connection between the first terminal 316 of the capacitor 300 and the conductive layer 668 of the embedded capacitor assembly 660. However, it should be understood that, in other embodiments, the terminal 316 can be exposed along the mounting surface 664. In such an embodiment, the embedded capacitor assembly 660 can be free of the via 665.

In some embodiments, the circuit board substrate 662 having the opening 667 defined therein can include multiple conductive layers 668, 672, e.g., multiple conductive traces, and the capacitor can include multiple terminals exposed along the first substrate surface, such as described with respect to the capacitor 400. A plurality of vias 665, 670 can extend from the terminals to the conductive layers of the circuit board substrate 662, e.g., at least one via can extend from a respective one terminal of the capacitor to a respective one conductive layer 668, 672 of the circuit board substrate 662.

The degree of which the capacitor is embedded depends on a variety of factors, such as the thickness of the circuit board substrate 662, the depth of the opening 667 (when the circuit board substrate 662 includes an opening 667), the thickness of the capacitor 100, 200, 300, 400, etc. The thickness of the circuit board substrate 662 (not including the attached electronic components) may be, in some embodiments, from about 0.1 to about 5 millimeters, in some embodiments, from about 0.2 to about 3 millimeters, and in some embodiments, from about 0.4 to about 1.5 millimeters. Thus, depending on the particular thicknesses employed, the capacitor may be embedded so that the exposed surfaces of the first terminal 116, 216, 316, 416 are substantially coplanar with or below the mounting surface 664 of the circuit board substrate 662. For instance, the capacitor 100, 200, 300, 400 can be embedded and enclosed within the opening 667 of the circuit board substrate 662. Alternatively, the capacitor 100, 200, 300, 400 may be embedded so that the exposed surfaces of the first terminal 116, 216, 316, 416 extend slightly above the mounting surface 664 of the circuit board substrate 662. Regardless, by at least partially embedding the capacitor 100, 200, 300, 400 in the circuit board substrate 662, the height profile or thickness occupied by the capacitor is decreased and may be controlled depending on the desired use.

It should be understood that various other electronic components may also be mounted onto the circuit board substrate 662 as is well known in the art and that a single capacitor is shown in FIGS. 6A and 6B only for purposes of illustration.

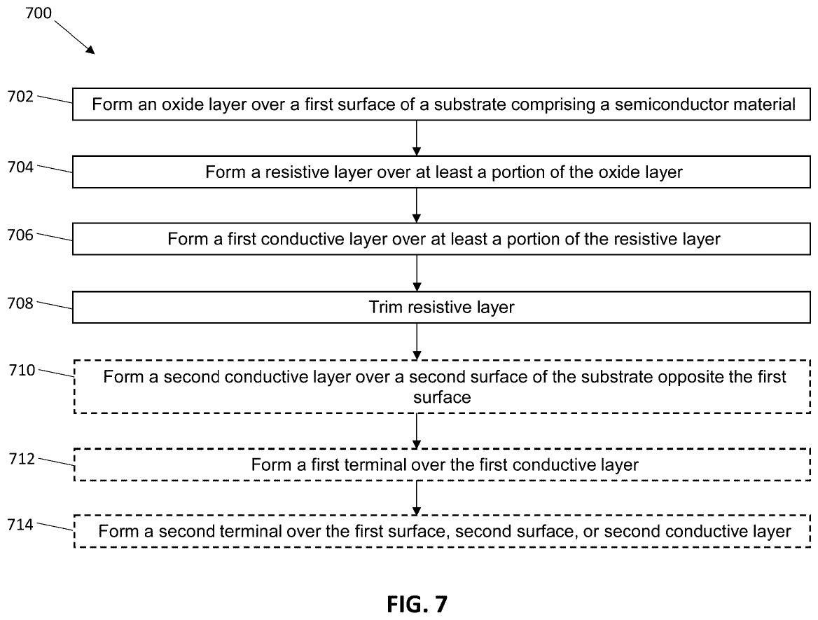

Referring now to FIG. 7, aspects of the present subject matter are directed to a method 700 for forming a capacitor such as described herein. For example, the method 700 will be described herein with reference to the capacitors 100, 200, 300, 400 described herein. However, it should be appreciated that the disclosed method 700 may be implemented with any suitable capacitor. In addition, although FIG. 7 depicts steps performed in a particular order for purposes of illustration and discussion, the methods discussed herein are not limited to any particular order or arrangement. One skilled in the art, using the disclosures provided herein, will appreciate that various steps of the methods disclosed herein can be omitted, rearranged, combined, and/or adapted in various ways without deviating from the scope of the present subject matter.

The method 700 can include (702) forming an oxide layer over a first substrate surface of a substrate comprising a semiconductor material. For example, the oxide layer can be grown in situ on the substrate. Lithography (e.g., photolithography) techniques can be used to define the shape of the oxide layer. For instance, for a capacitor 400 having an oxide layer 408 as described with respect to FIGS. 4A and 4B, portions of the oxide layer 408 can be removed through etching such that the oxide layer 408 is located within the first portion 401 of the first substrate surface 404 of the substrate 402.

The method 700 can include (704) forming a resistive layer over at least a portion of the oxide layer. The resistive layer can be deposited over the oxide layer such that the resistive layer is contained within a perimeter of the oxide layer, or the resistive layer can extend to the edges of the oxide layer. The resistive layer can be free of direct contact and/or direct electrical connection with the substrate. The resistive layer can have a thickness less than about 10 microns. The resistive layer can be formed from tantalum nitride, chromium silicon, or other suitable resistive material such as described herein.

The method 700 can include (706) forming a first conductive layer over at least a portion of the resistive layer. The first conductive layer can be deposited over the resistive layer such that a trimmable area of the resistive layer is left exposed. For instance, the first conductive layer can be contained within a perimeter of the resistive layer, e.g., such that the trimmable area is defined along each edge of the first conductive layer, or the first conductive layer can be aligned with one or more edges of the resistive layer such that the trimmable area is defined along the edge(s) of the first conductive layer that are not aligned with the resistive layer. For instance, forming the first conductive layer may include depositing at least one edge of the first conductive layer along at least one edge of the resistive layer such that the at least one edge of the first conductive layer is aligned with the at least one edge of the resistive layer. In some embodiments, forming the first conductive layer comprises depositing at least one edge of the first conductive layer spaced apart from at least one edge of the resistive layer, i.e., the at least one edge of the first conductive layer is spaced apart from at least one edge of the resistive layer when the first conductive layer is deposited over the resistive layer. The first conductive layer can be free of direct contact and/or direct electrical connection with the oxide layer and/or the substrate.

The method 700 can include (708) trimming the resistive layer. As described herein, a laser or other suitable device can be used to trim or remove at least a portion of the trimmable area of the resistive layer, which reduces the resistive layer area to thereby reduce the capacitance value of the capacitor. For example, the capacitance value can range from a minimum capacitance value, defined by the conductive layer area of the first conductive layer, and a maximum capacitance value, defined by the resistive layer area of the resistive layer prior to trimming. By trimming the resistive layer, the resistive layer area is reduced below its original, maximum area, which in turn reduces the capacitance value of the capacitor below its maximum capacitance value such that the capacitance value of the capacitor after trimming the resistive layer is closer to (if only a portion of the trimmable area is removed) or the same as (if all of the trimmable area is removed) the minimum capacitance value. As described herein, lasering the resistive layer to trim the resistive layer can include using a laser set to a power level below a breakdown voltage of the oxide layer, which can help protect the oxide layer or lower the potential for damage to the oxide layer.

As stated, trimming the resistive layer may include lasering the resistive layer to remove a portion of the resistive layer. In some embodiments, trimming the resistive layer includes removing a strip of resistive layer in an X-direction and a Y-direction, such as illustrated in FIGS. 1B and 1C, where a strip of the trimmable area 115 is removed along the second edge 112b of the conductive layer 112, or in FIGS. 2B and 2C, where a strip of the trimmable area 215 is removed to reduce the size of the trimmable area 215 adjacent the second edge 212b of the conductive layer 212. In other embodiments, trimming the resistive layer includes removing the resistive layer in one or more patterns or shapes, such as removing a generally square shaped portion of the resistive layer (e.g., as illustrated in FIG. 1D), removing both a strip of the resistive layer and a generally square shaped portion of the resistive layer, or removing the resistive layer in other patterns or shapes.

The method 700 can optionally include (710) forming a second conductive layer over at least a portion of a second substrate surface of the substrate. The second substrate surface of the substrate can be opposite the first substrate surface of the substrate. Forming the second conductive layer can include depositing a conductive material over the second substrate surface as described herein.

The method 700 can optionally include (712) forming a first terminal over the first conductive layer, such as by depositing a conductive material over the first conductive layer. For instance, in some embodiments, a separate first terminal may be formed over the first conductive layer, but in other embodiments, the first conductive layer may form the first terminal.

The method can also optionally include (714) forming a second terminal such that at least the substrate, the oxide layer, and the resistive layer are disposed between the first conductive layer and the second terminal. For example, as described herein, in some embodiments the second conductive layer may form the second terminal. In other embodiments, the second terminal may be formed over the second conductive layer such that the substrate, the oxide layer, the resistive layer, and the second conductive layer are disposed between the first conductive layer and the second terminal. The second terminal may be formed by depositing a conductive material over the desired surface. For example, the conductive material may be deposited directly on the first substrate surface of the substrate or directly on the second substrate surface of the substrate to form the second terminal on the first substrate surface or the second substrate surface, respectively, or the conductive material may be deposited directly on the second conductive layer to form the second terminal on the second conductive layer.

Alternatively, in some embodiments such as described with respect to the capacitor 400, the second terminal 418 may be formed over the first substrate surface 404 of the substrate 402 such that the second terminal 418 is connected with the substrate 402. As such, both the first terminal 416 and the second terminal 418 are formed over the first substrate surface 404 of the substrate 402, and both of the first terminal 416 and the second terminal 418 can be exposed along the first substrate surface 404 of the substrate 402 for surface mounting the capacitor 400. In any event, the pair of terminals are connected to various layers or substrate of the respective capacitor such that a resistor and a capacitor are formed in series with one another.

### Applications

The capacitor described herein is useful in a variety of applications. For example, the capacitor described herein can replace two parts with a single part where a resistor and capacitor are used inline. Further, the capacitor may be particularly useful in broadband devices, providing a broadband capacitor response for bias and Vdd lines. Additionally, or alternatively, the capacitor may be particularly useful for impedance matching circuits, transition transmission lines, and/or coupling circuitry.

These and other modifications and variations of the present invention may be practiced by those of ordinary skill in the art, without departing from the spirit and scope of the present invention. In addition, it should be understood that aspects of the various embodiments may be interchanged both in whole or in part. Further, those of ordinary skill in the art will appreciate that the foregoing description is by way of example only and is not intended to limit the invention so further described in such appended claims.

What is claimed is:

1. A capacitor comprising:
a substrate comprising a semiconductor material, the substrate having a first substrate surface;
an oxide layer formed over the first substrate surface, the first substrate surface defined in an X-Y plane, the X-Y plane defined by an X-direction and a Y-direction perpendicular to the X-direction;
a resistive layer formed over at least a portion of the oxide layer, the resistive layer having a resistive layer area in a first plane parallel to the X-Y plane; and
a first conductive layer formed over at least a portion of the resistive layer, the first conductive layer having a first conductive layer area in a second plane parallel to the X-Y plane, the first conductive layer area smaller than the resistive layer area,
wherein the capacitor comprises a capacitance value in a range from a minimum capacitance value to a maximum capacitance value, and
wherein the resistive layer area is configured to be trimmed to reduce the capacitance value of the capacitor to less than the maximum capacitance value.

2. The capacitor of claim 1, wherein the resistive layer area defines the maximum capacitance value and the first conductive layer area defines the minimum capacitance value.

3. The capacitor of claim 1, wherein the resistive layer defines a trimmable area, and wherein the trimmable area is free of the first conductive layer.

4. The capacitor of claim 3, wherein the trimmable area is defined adjacent at least one edge of the first conductive layer.

5. The capacitor of claim 1, wherein the area of the resistive layer is configured to be trimmed by a laser.

6. The capacitor of claim 5, wherein the laser is set to a power level less than a breakdown voltage of the oxide layer.

7. The capacitor of claim 1, wherein at least one edge of the first conductive layer is aligned with an edge of the resistive layer in the X-direction or the Y-direction.

8. The capacitor of claim 1, further comprising:
a second conductive layer formed over a second substrate surface, the second substrate surface opposite the first substrate surface.

9. The capacitor of claim 8, further comprising:
a first terminal connected with the first conductive layer; and
a second terminal connected with the second conductive layer.

10. The capacitor of claim 1, further comprising:
a first terminal connected with the first conductive layer; and
a second terminal connected with the first substrate surface, wherein the oxide layer is connected in series between the substrate and the first conductive layer to form a capacitor between the first terminal and the second terminal.

11. The capacitor of claim 10, wherein each of the first terminal and the second terminal are exposed along the first substrate surface for surface mounting the capacitor.

12. The capacitor of claim 10, wherein the second terminal comprises an electrically conductive material that directly contacts the first substrate surface.

13. The capacitor of claim 1, wherein the semiconductor material of the substrate comprises silicon.

14. The capacitor of claim 1, wherein the resistive layer is formed from tantalum nitride.

15. A method of forming a capacitor, the method comprising:
forming an oxide layer over a first substrate surface of a substrate, the substrate comprising a semiconductor material;
forming a resistive layer over at least a portion of the oxide layer;
forming a first conductive layer over at least a portion of the resistive layer; and
trimming the resistive layer.

16. The method of claim 15, wherein trimming the resistive layer comprises lasering the resistive layer to remove a portion of the resistive layer.

17. The method of claim 16, wherein lasering the resistive layer comprises using a laser set to a power level below a breakdown voltage of the oxide layer.

18. The method of claim 15, wherein the capacitor comprises a capacitance value in a range from a minimum capacitance value to a maximum capacitance value, wherein the minimum capacitance value is defined by a first conductive layer area of the first conductive layer and the maximum capacitance value is defined by a resistive layer area of the resistive layer, and wherein trimming the resistive layer decreases the resistive layer area to reduce the capacitance value of the capacitor to less than the maximum capacitance value.

19. The method of claim 15, wherein trimming the resistive layer comprises removing a strip of resistive layer in an X-direction and a Y-direction.

20. An embedded capacitor assembly comprising:
a circuit board substrate having a mounting surface; and
a capacitor at least partially embedded within the circuit board substrate, the capacitor comprising:
a substrate comprising a semiconductor material, the substrate having a first substrate surface;
an oxide layer formed over the first substrate surface, the first substrate surface defined in an X-Y plane, the X-Y plane defined by an X-direction and a Y-direction perpendicular to the X-direction;
a resistive layer formed over at least a portion of the oxide layer, the resistive layer having a resistive layer area in a first plane parallel to the X-Y plane; and
a first conductive layer formed over at least a portion of the resistive layer, the first conductive layer having a first conductive layer area in a second plane parallel to the X-Y plane, the first conductive layer area smaller than the resistive layer area,
wherein the capacitor comprises a capacitance value in a range from a minimum capacitance value to a maximum capacitance value,
wherein the resistive layer area is configured to be trimmed to reduce the capacitance value of the capacitor to less than the maximum capacitance value, the resistive layer defining a trimmable area that is free of the first conductive layer, and
wherein the resistive layer area defines the maximum capacitance value and the first conductive layer area defines the minimum capacitance value.
